(19) United States
(12) Patent Application Publication
(10) Pub. No.: US 2005/0124097 A1
(43) Pub. Date: Jun. 9, 2005

(54) Integrated circuit with two phase fuse material and method of using and making same

(75) Inventor: Qi Xiang, San Jose, CA (US)

Correspondence Address: AMD-MKE C/O FOLEY LARDNER, 777 EAST WISCONSIN AVENUE, MILWAUKEE, WI, 53202-5367, US

(73) Assignee: Advanced Micro Devices, Inc

(21) Appl. No.: 10/729,194

(22) Filed: Dec. 5, 2003

(51) Int. Cl. H01L 21/479; H01L 21/82; H01L 21/326; H01L 29/00

(52) U.S. Cl. 438/132; 438/467

(57) ABSTRACT

A method of programming a fuse utilizes a fuse including a material having a first phase and a second phase. The first phase has a different resistivity than the second phase. The method includes providing a current or voltage to the fuse and changing the material from the first phase to the second phase with the current. The material can be a silicide material such as nickel silicide.

### FIELD OF THE INVENTION

The present invention relates generally to fuses for integrated circuits (ICs). More particularly, the present invention relates to a fuse structure and process for fabricating and programming fuses in integrated circuits.

### BACKGROUND OF THE INVENTION

Various types of integrated circuits (ICs) utilize fuse devices to permanently store information, to form permanent connections on circuits, or to otherwise configure an IC after it is manufactured. Such fuse devices include structures or materials for forming fusible connections which can be programmed from one state to another state. The programmed state can represent information to complete a circuit connection, drive circuitry, or to otherwise configure the IC.

Fuses are frequently utilized in complimentary metal oxide semiconductor (CMOS) ICs such as layer circuits, microprocessors, memory devices, application specific integrated circuits (ASICs), etc., as well as other electronic circuits. Hereinafter, the term “fuse” is used to describe any IC element or structure that can permanently store information, form permanent connections or configure on an IC after the IC has been fabricated or substantially fabricated.

Fuses are utilized in a variety of applications. For example, fuses are used to program redundant elements and to replace identical defective elements in logic circuits and memory circuits. Fuses can also be used to store identification numbers for integrated circuit dies or other information. In the field of microprocessors, communication circuits, and other logic circuits, fuses can be used to adjust the speed of the circuit by adjusting the resistance of the signal path.

Conventional fuses include electrically erasable programmable read only memory (EEPROM) cells and oxide anti-fuses. Conventional fuses based upon EEPROM cells generally need either thick oxide structures to sustain charge on a floating node or much higher voltages than normal operating supply voltages for programming. Similarly, oxide anti-fuses generally require much higher voltages than normal operating supply voltages for programming. High voltages can destroy components formed by the latest fabrication technologies.

Other conventional fuses include laser programmable links. Laser programmable links are generally opened after the semiconductor is processed and passivated but before it is packaged. The process utilizes an extra processing step to open (e.g., blow) the fuse with a laser and requires precise alignment to focus the lasers on the proper link. The programming step can result in damage to the device and to passivated layers.

Other conventional fuses have utilized polysilicide fuse elements which are opened by providing a programming signal. Generally, a polysilicide fuse element is agglomerated by the programming signal. The polysilicide materials for the fuse element can include cobalt silicide (CoSi₂) and titanium silicide (TiSi₂). Generally, a relatively high programming voltage is required to generate enough heat to agglomerate the polysilicide fuse element associated with conventional fuse devices. As discussed above, higher voltages are not desirable for use in ICs manufactured by the latest process technologies.

Thus, there is a need for a fuse that can be programmed at a low voltage. There is a further need for a method of programming a fuse that does not require a high voltage or laser. Further, there is a need for a silicide fuse which does not require agglomeration for programming. Yet further still, there is a need for a method of manufacturing a fuse which can be programmed at lower voltages after the IC is completed. Further still, there is a need for a method of programming a fuse without agglomeration and a method of making such a fuse.

### BRIEF SUMMARY OF THE INVENTION

An exemplary embodiment relates to a method of programming a fuse. The fuse includes a material having a first phase and a second phase. The first phase has a different resistivity than the second phase. The method includes providing a current to the fuse and changing the material from the first phase to the second phase with the current.

Another exemplary embodiment relates to a fuse for an integrated circuit. The fuse includes a material capable of existing in a first phase or a second phase in response to at least one of a current signal and a voltage signal. The fuse has different resistance in the first phase than in the second phase.

Still another exemplary embodiment relates to an integrated circuit. The integrated circuit includes a polysilicon layer disposed above an insulative structure and a silicide layer disposed above the polysilicon layer. The silicide layer is a first type and is convertible to a silicide layer of a second type in response to a signal. A resistance of the silicide layer changes when the silicide layer is converted from the first type to the second type.

Yet another exemplary embodiment relates to a process of manufacturing a fuse for an integrated circuit. The process includes providing a silicide layer above a layer including silicon and patterning the silicide layer. The layer including silicon is above a bulk silicon substrate or a field oxide structure. The silicide layer is patterned in accordance with a fuse pattern. The silicide layer is in a first phase which is convertible to a second phase. The first phase has a different resistance characteristic than the second phase.

### BRIEF DESCRIPTION OF THE DRAWINGS

Preferred embodiments will become more fully understood from the following detailed description, taken in conjunction with the accompanying drawings, wherein like reference numerals denote like elements, in which:

FIG. 1 is a top planar view schematic drawing of a portion of an integrated circuit including a fuse in accordance with an exemplary embodiment;

FIG. 2 is a cross-sectional view schematic drawing of the portion illustrated in FIG. 1 taken at line 2-2;

FIG. 3 is a cross-sectional view schematic drawing of the portion illustrated in FIG. 1 taken at line 3-3;

FIG. 4 is a cross-sectional view schematic drawing of a portion of an integrated circuit including another fuse in accordance with an alternative embodiment;

FIG. 5 is a cross-sectional view schematic drawing of a portion of an integrated circuit including still another fuse in accordance with another alternative embodiment;

FIG. 6 is a cross-sectional view schematic drawing of a portion of an integrated circuit including another fuse taken about line 3-3 in accordance with still another alternative embodiment;

FIG. 7 is an enlarged cross-sectional view schematic drawing of the portion of the integrated circuit illustrated in FIG. 3, showing the fuse in a non-programmed state; and

FIG. 8 is an enlarged cross-sectional view schematic drawing of the portion of the integrated circuit illustrated in FIG. 3, showing the fuse in a programmed state.

### DETAILED DESCRIPTION OF THE EXEMPLARY EMBODIMENTS

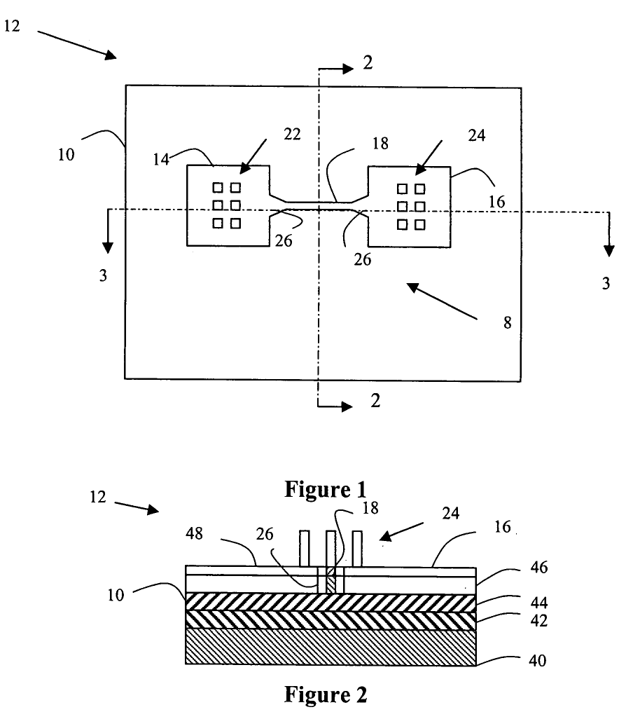

With reference to FIGS. 1-9, an exemplary embodiment of an advantageous structure and process of programming an integrated circuit (IC) fuse is described. The advantageous structure and process is preferably implemented using a material which has a first phase and a second phase. The resistivity of the material in the first phase is different than the resistivity of the material in the second phase. The material can be fabricated according to a silicidation process.

In one embodiment, the resistivity in the first phase is greater than the resistivity in the second phase. In an alternative embodiment, the fuse structure can be designed so that the material consumes a doped layer in the fuse structure to further reduce the conductivity of the fuse when programmed. The fuse can be used to drive transistors, store information, connect or disconnect circuits, etc.

With reference to FIG. 1, a portion 10 of an integrated circuit (IC) 12 includes a fuse 8. Preferably, fuse 8 is disposed above a top surface of a substrate or other layer utilized in integrated circuit processes. Fuse 8 can be utilized for any number of IC applications using fuses, for example applications where electrically erasable programmable read only memory (EEPROM) cells, laser fuses, oxide anti-fuse devices, and polysilicide fuse devices are utilized.

Fuse 8 is ideal for use in present IC process technologies that are designed for low voltage applications. Fuse 8 is preferably part of a larger integrated circuit device such as IC 12. Preferably, the fuse pattern for fuse 8 is relatively small and therefore requires little space on IC 12.

In general, fuse 8 can be utilized to provide any discretionary connection or storage function for IC 12. Fuse 8 can be coupled with transistors or other switching devices to engage or disengage circuitry. Fuse 8 is shown in FIGS. 1-3 and 7-8 as not connected to any particular circuitry because the scope of the present application is not restricted to any particular IC fuse application. Fuse 8 can be used in any area in an integrated circuit where storage or selection is desired.

Advantageously, fuse 8 can be permanently programmed after IC 12 is packaged or during the IC fabrication process. Fuse 8 can be advantageously programmed at relatively low voltages such that it can be programmed without destroying structures associated with the latest process technologies. More particularly, fuse 8 can be programmed without destructive damages to overlying dielectrics and underlying silicon layers. Further, fuse 8 does not have to be exposed to air to be programmed unlike certain conventional prior art fuses.

As shown in FIGS. 1, 2, and 3, fuse 8 is provided above a substrate such as a semiconductor substrate 40. In one embodiment, semiconductor substrate 40 is a single crystalline silicon substrate provided on a conventional IC wafer. A buried oxide (BOX) layer or other insulative layer 42 can be provided above substrate 40. A field oxide layer 44 can be provided above layer 42. Field oxide layer 44 can be any insulative structure or layer. In one embodiment, field oxide layer 44 is provided in the active layer above layer 42. Layer 44 can be fabricated in a local oxidation of silicon (LOCOS) process and have an elliptical shape with bird's beaks.

Fuse 8 preferably has a fuse pattern shape including square regions 14 and 16 connected by a narrow portion 18. The fuse pattern can be entirely disposed above a LOCOS structure (e.g., layer 44) to save IC area for chip interconnections to the active layer. Alternatively, fuse 8 can be disposed above other structures including active layers, transistors, etc. Narrow portion 1 8 serves as a fuse element which can be programmed into a programmed state.

Narrow portion 1 8 of the fuse pattern is coupled to square shaped regions or portions 14 and 16 by trapezoidal regions 26. Fuse 8 can be designed to have a variety of geometric patterns. Although shown in a barbell-shaped pattern, fuse 8 can have different patterns without departing from the scope of the invention. For example, regions 14 and 16 can be round, rectangular, or other shapes. Portion 18 can have an arcuate shape, a zigzag shape, or another geometric pattern.

The size of fuse 8 can also be adjusted in accordance with application parameters and design criteria. For example, the size of the pattern for fuse 8 can be the minimum width associated with the active region for the process design rule. The minimum width can vary with different process technologies, shallow trench isolation (STI) space considerations, proximity effect, and other fuse design requirements. In one embodiment, square shaped regions 14 have dimensions of 500 nm by 500 nm and narrow portion 18 has a length of 1300 nm and a width of 130 nm. Fuse 8 can also have alternative dimensions.

A set of contacts 22 can connect to square shaped region 1 4 and a set of contacts 24 can connect to portion 1 6. In the preferred embodiment, sets 22 and 24 each include six contacts provided through conductive vias in an insulative layer. In this manner, regions 14 and 1 6 serve as terminals of fuse 8. Preferably, contacts 22 and 24 are provided in parallel and can be used to reduce contact resistance and ensure that overheating does not occur within contacts 22 and 24. Contacts 22 and 24 can each have an area of between approximately 0.02 micrometers squared and 0.04 micrometers squared (minimums). Alternative sizes and shapes for sets 22 and 24 of contacts can be utilized. Contacts 22 and 24 can be coupled to interconnect layers above fuse 8 and eventually to package terminals.

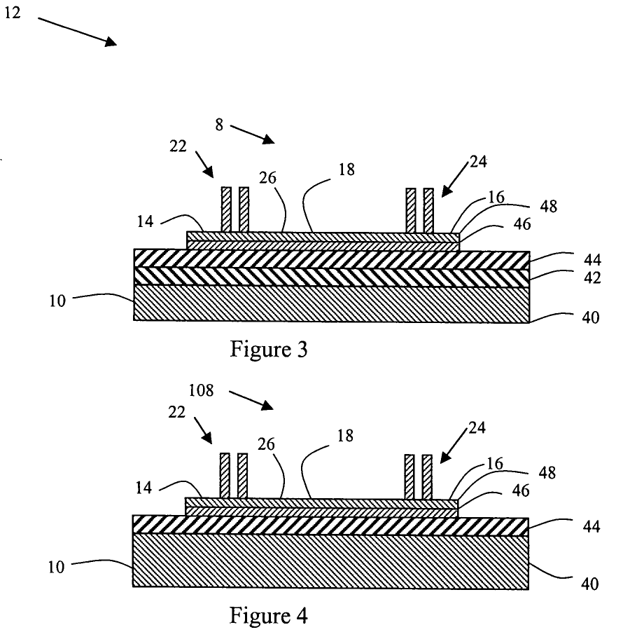

With reference to FIGS. 2-3, fuse 8 includes a silicon-containing layer or polysilicon layer 46 and a silicide-containing layer or silicide layer 48. In a preferred embodiment, layer 46 is a layer of polysilicon having a thickness of between approximately 500 Å and 2000 Å provided on an insulator film or layer 44 having a thickness of between approximately 0.5 micron and 2 micron. Layer 46 can be a doped or undoped polysilicon layer. Layer 42 can be N-doped or P-doped. Layer 44 can be a silicon dioxide or silicon nitride material. Preferably, layer 46 is deposited by CVD above layer 44. Alternatively, other deposition or growth processes can be utilized to provide layer 46.

After layer 46 is deposited, a silicide layer is formed above layer 46. Preferably, layer 48 is formed by depositing a layer of metal (e.g., a refractory metal) and heating at an elevated temperature to form a silicide material. In one example, silicide layer 44 is a mononickel silicide (NiSi) layer. Layer 48 can be formed by depositing a nickel layer by CVD or sputtering and annealing to complete layer 48.

Layers 46 and 48 can be lithographically patterned to form the shape of fuse 8. Layers 46 and 48 can be etched by dry etching. In one embodiment, layer 48 is etched as a metal layer before silicidation.

In one embodiment, a nickel layer having a thickness of between approximately 50 and 200 Å is deposited by CVD to form layer 48. The nickel layer is annealed at a temperature of between approximately 300 and 600° C. to form mononickel silicide. Alternative silicidation techniques can be utilized to form layer 48 above layer 44. Further, layer 48 can be other materials capable of achieving different phases for indication of a programmed or non-programmed state. In a non-programmed state, layer 48 is in a first phase (e.g., a mononickel silicide phase). Preferably, layer 48 is a mononickel silicide phase having a lower resistivity. In one example, layer 48 has a sheet resistance of 1-5 ohms per square in the mononickel silicide phase.

When fuse 8 is programmed, a voltage or current signal is provided to fuse 8, and an electrical discontinuity is formed due to the change of phase in layer 48. Preferably, layer 48 is changed into a second phase of nickel silicide such as nickel disilicide (NiSi₂). The change of phase to nickel disilicide increases the resistance of fuse 8 due to the higher sheet resistance of nickel disilicide.

In one example, layer 48 has a sheet resistance of 10-40 ohms per square when programmed (e.g., programming increases the sheet resistance from 1-5 ohms per square to 10-40 ohms per square). Preferably, programming fuse 8 increases its resistance from at least two times or even at least eight times its non-programmed resistance. More preferably, the resistance of fuse 8 increases approximately 10 times as it changes from its non-programmed to its programmed state.

The energy required for changing of phase of layer 48 is substantially less than required for agglomeration with conventional fuses such as cobalt silicide and titanium silicide fuses. As a result, the programming voltage and/or current for fuse 8 is substantially smaller. The required programming voltage and/or current varies depending upon the thickness of layer 48, parameters associated with layer 46, and the sizes of the fuse patterns (e.g., the width of the fuse element or portion 18). In one embodiment, a current between approximately 5 microampere and 20 microampere and a voltage between approximately 1 and 4 V programs fuse 8 including a 300 Å thick layer 48 of mononickel silicide.

FIG. 4 shows an alternative embodiment of fuse 8. Fuse 108 is substantially similar to fuse 8 described with reference to FIGS. 1 -3. Fuse 108 includes structures and layers similar to the structures and layers of fuse 8 described above. In FIG. 4, fuse 108 is substantially similar to fuse 8, and similar reference numerals indicate similar structures. The semiconductor substrate (e.g., a bulk semiconductor substrate) of fuse 108 is different than the silicon on insulator (SOI) substrate discussed with reference to FIGS. 2 and 3.

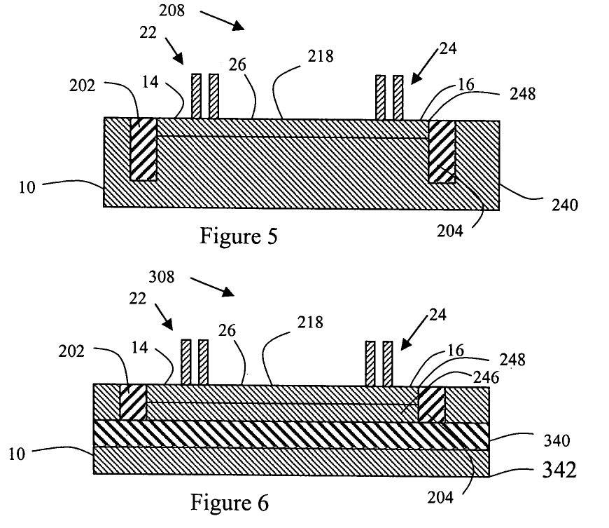

With reference to FIG. 5, a fuse 208 is substantially similar to fuse 8. Fuse 208 is provided between shallow trench isolation structures 202 and 204, and includes a layer 218 of silicide substantially similar to layer 48 described above with reference to FIGS. 2-3. However, layer 218 is provided directly within bulk semiconductor substrate 240. Preferably, semiconductor substrate 240 is a single crystalline semiconductor substrate.

In one alternative, a layer 248 can be provided slightly above a top surface of the bulk semiconductor substrate. Layer 218 can be formed according to the silicidation processes described above.

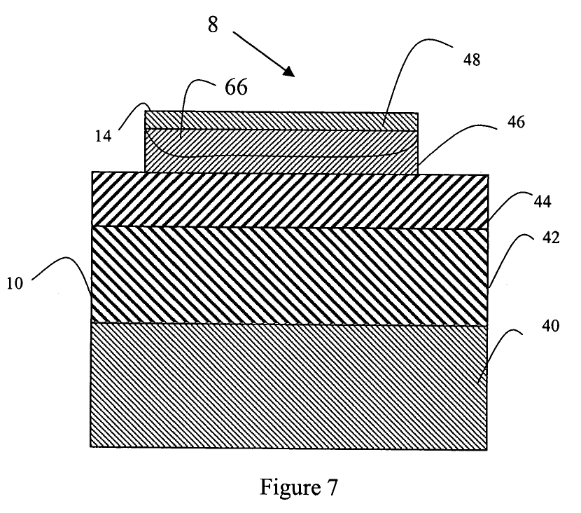

With reference to FIG. 6, a fuse 308 is similar to fuse 208 except that it is provided on a silicon-on-insulator substrate including a buried oxide layer 340 and a base layer 342. Layer 218 is provided above an active silicon layer 246. Similar reference numerals in FIG. 6 refer to similar elements in FIGS. 1-5.

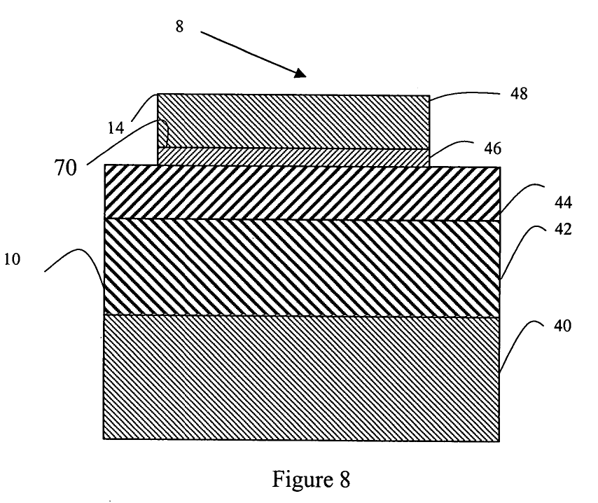

With reference to FIGS. 7 and 8, an enlarged cross-sectional drawings show layers 46 and 48. The discussion in FIGS. 7 and 8 applies to layers 246 and 248 as well as to layers 46 and 48.

In FIG. 7, fuse 8 is in an unprogrammed state. Layer 46 can be doped to have a doping region 66. Region 66 can be doped with N-type or P-type dopants. Preferably, an energy of between approximately 1 KeV and 20 KeV at a dose of between approximately 1×10¹⁴ and 1×10¹⁵ is utilized to provide region 66 with a depth of between 100 Å and 1000Å. Region 66 can be formed by ion implantation or another doping technique. Dopants can include boron (B), arsenic (AS), phosphorous (P), boron difluoride (BF₂), or any appropriate dopant.

In the unprogrammed state, layer 48 is preferably a silicide layer in low resistance phase, such as a mononickel silicide layer. Region 66 contributes to the low resistance of fuse 8.

With reference to FIG. 8, fuse 8 has been subjected to a programming signal such that layer 48 is changed from a first phase to a phase having a higher resistance characteristic or resistivity (e.g., a second phase). In the programmed state, layer 48 is a different type of silicide than in a non-programmed state. In one embodiment, layer 48 is changed to nickel disilicide (NiSi₂). In addition, layer 48 can grow such that a bottom surface consumes a portion of layer 46. Preferably, a bottom 70 of layer 48 extends until all of or a large portion of doped region 66 of layer 46 is consumed. In this manner, the resistivity of fuse 8 is further increased due to the absence of doped region 66. In a preferred embodiment, region 66 is entirely consumed during silicidation.

It is understood that while the preferred embodiments and specific examples are given, these embodiments and examples are for the purpose of illustration only and are not limited to the precise details described herein. For example, other geometries can benefit from the advantageous fuse design. Various modifications may be made in the details within the scope and range of the equivalence of the claims without departing from what is claimed.

1. A method of programming a fuse, the fuse including a material having a first phase and a second phase, the first phase having a different resistivity than the second phase, the method comprising:
providing a current to the fuse; and
changing the material from the first phase to the second phase with the current.

2. The method of claim 1, wherein the second phase is a relatively higher resistance than the first phase.

3. The method of claim 2, wherein the current is a programming current.

4. The method of claim 3, wherein the material has a first sheet resistance in the second phase of at least two times of a second sheet resistance in the second phase.

5. The method of claim 4, the first sheet resistance is at least 8 times the second sheet resistance.

6. The method claim 4 wherein the first sheet resistance is approximately 10 times the second sheet resistance.

7. The method of claim 1, wherein the material includes nickel.

8. The method of claim 7, wherein the material is a silicide.

9. The method of claim 7, wherein first phase includes mononickel silicide and the second phase includes nickel disilicide.

10. The method of claim 9, wherein the first phase has a sheet resistance between 1-5 ohms per square.

11. The method of claim 10, wherein the second phase has a sheet resistance between 10 and 40 ohms per square.

12. A fuse for an integrated circuit, the fuse comprising a material capable of existing in a first phase or a second phase in response to at least one of a current signal and a voltage signal, the fuse having a different resistance in the first phase than in the second phase.

13. The fuse of claim 12, wherein the fuse further comprises a layer of material including silicon and a silicide layer.

14. The fuse of claim 12, wherein the silicide includes nickle.

15. The fuse of claim 12, wherein first phase includes mononickel silicide and the second phase includes nickel disilicide.

16. An integrated circuit comprising:
a polysilicon layer disposed above an insulative structure; and
a silicide layer disposed above the polysilicon layer, the silicide layer being a first type and being convertible to a silicide layer of a second type in response to a signal, wherein a resistance of the silicide layer changes when the silicide layer is converted from the first type to the second type.

17. The integrated circuit of claim 15, wherein the silicide layer of the first type is mononickel silicide.

18. The integrated circuit of claim 16, wherein the silicide layer of the second type is nickel disilicide.

19. The integrated circuit of claim 17, wherein the insulative structure is a field oxide or an insulative layer.

20. A process of manufacturing a fuse for an integrated circuit, the process comprising:
providing a silicide layer above a layer including silicon, the layer including silicon being above a bulk silicon substrate or a field oxide structure; and
patterning the silicide layer in accordance with a fuse pattern, wherein the silicide layer is in a first phase, the first phase being convertible to a second phase, the first phase having a different resistance characteristic than the second phase.

21. The process of claim 1 9 further comprising:
providing conductive vias at a first end and a second end of the fuse pattern.
